(19) United States
(12) Patent Application Publication
(10) Pub. No.: US 2006/0189181 A1
(43) Pub. Date: Aug. 24, 2006

(54) Method of forming a circuit structure

(75) Inventor: Hiroyuki Murakoshi, Shizuoka (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Yazaki Corporation

(21) Appl. No.: 11/404,074

(22) Filed: Apr. 14, 2006

Related U.S. Application Data
(62) Division of application No. 10/450,471, filed on Oct. 31, 2003.

(30) Foreign Application Priority Data
Dec. 15, 2000 (JP) 2000-382569

(51) Int. Cl. H05K 1/00

(52) U.S. Cl. 439/76.2

(57) ABSTRACT

Having a wiring board 1 having a plurality of pressure-welding terminals 3 and an insulating substrate 4 supporting the pressure-welding terminals 3, wires 2, 2′ are welded under pressure to the pressure-welding terminal 3 on the wiring board 1, for electrical connection. By wiring the plural wires 2 on the wiring board 1 straight in a horizontal direction of the wire board 1; wiring the plural wires 2′ in a vertical direction crossing the above wiring direction; and electrically conducting necessary ones of intersections defined by the wires 2 in the horizontal direction and the wires 2′ wired in the vertical direction, a desired circuit can be established on the board.

### TECHNICAL FIELD

The present invention relates to both circuit structure and circuit forming method for an electrical connection box which is used for interconnection of wire-harness etc.

### BACKGROUND ART

FIG. 1 is a plan view showing the circuit structure for electrical connection box under our proposal, showing an example illustrative of forming an inside circuit by a wiring board, wires and pressure-welding terminals. In the circuit structure for electrical connection box shown in FIG. 1, a plurality of pressure-welding terminals 21(21a, 21b, 21c, . . . ) are arranged on the wiring board 20 made from an insulating substrate, while a plurality of wires 29 (22a, 22b, 22c, . . . ) are pressure-fitted to the pressure-welding terminals 21 (21a, 21b, 21c, . . . ) for connection, establishing a desired branch circuit. The so-established circuit structure is accommodated in a receiving casing 23 shown in FIG. 2.

On the wiring board 20, the plural wires 22 (22a, 22b, 22c, . . . ) are wired just like curved lines. At wires intersections existing among the pressure-welding terminals 21 (21a, 21b, 21c, . . . ), these wires 22 (22a, 22b, 22c, . . . ) are laid to overlap each other.

For the above-mentioned conventional circuit structure where the plural wires 22 (22a, 22b, 22c, . . . ) are wired like curved lines, however, a wiring machine has to turn its wiring head for the wires 22 (22a, 22b, 22c, . . . ) at their bending points in the course of wiring the wires among the pressure-welding, terminals 21 (21a, 21b, 21c, . . . ) while taking a lot of time for the wiring operation. Consequently, there arises a problem that a requirement of establishing more wiring machines would cause the installation cost to be increased.

Additionally, since the plural wires 22 (22a, 22b, 22c, . . . ) overlap each other at the intersections, a space that the wiring board 20 occupies in-height is increased as the number of wires overlapping increases, causing the electrical connection box to be large-sized. Contrary, if the number of wires 22 (22a, 22b, 22c, . . . ) overlapping is restricted to prevent the above problem, then there arises a new problem of difficulty to arrange the wires on the wiring board.

### SUMMARY OF THE INVENTION

In consideration of the above-mentioned problems, the object of the invention is to provide both circuit structure and circuit forming method for electrical connection box, both of which can provide both improved workability in arranging the wires and reduced installation cost and furthermore, which can save a space occupied by the wired wires in height.

According to accomplish the above-mentioned object, there is provided a circuit structure for electrical connection box, comprising:

a wiring board having an insulating substrate;

a plurality of first wires wired straight in a first direction defined on the wiring board at predetermined intervals;

a plurality of second wires wired straight in a second direction defined on the wiring board at predetermined intervals, the second wires crossing the first wires at respective intersections; and

a plurality of pressure-welding terminals supported on the insulating substrate, for electrically connecting the first wires with the second wires;

wherein the pressure-welding terminals are fitted on some of the intersections under pressure thereby to establish a designated circuit on the wiring board.

According to the circuit structure for electrical connection, the above-mentioned bending points of the wires can be eliminated since the first and second wires are wired straight in two directions: the first direction and the second directions crossing the first direction at the intersections. Thus, since it becomes unnecessary to turn the wiring head in the course of wiring the wires by the wiring machine, it is possible to shorten a period required for the wiring operation. Correspondingly, it becomes possible to reduce the number of wiring machines, also reducing the installation cost.

Additionally, owing to the above-mentioned arrangement of the first and second wires, each overlap of these wires consists of two wires at most, so that the wiring board can be lowered in height thereby to save a space occupied by the wiring board in height. The second feature of the invention resides in that, in the above circuit structure, the first wires and the second wires are together covered with insulating covers respectively.

The third feature of the invention resides in that, in the above circuit structure, the first direction is identical to a horizontal direction defined on the wiring board and the second direction is identical to a vertical direction substantially perpendicular to the horizontal direction.

As the fourth feature of the invention, there is also provided a circuit structure for electrical connection box, comprising:

a wiring board having an insulating substrate;

a plurality of first wires wired straight in a first direction defined on the wiring board at predetermined intervals; and

a plurality of second wires wired straight in a second direction defined on the wiring board at predetermined intervals, the second wires crossing the first wires at respective intersections;

wherein, at the some intersections, the first wires are welded to the second wires respectively for effecting electrical conductivity between the first wires and the second wires thereby to establish a designated circuit on the wiring board.

According to the above circuit structure for electrical connection box, in addition to effects similar to the former circuit structure, it is possible to establish the designated circuit without using the pressure-welding terminals, improving the workability in connecting the wires.

The fifth feature of the invention resides in that, in the, above circuit structure, the first wires and the second wires are together covered with insulating covers respectively.

The sixth feature of the invention resides in that, at the some intersections, the first wires are connected with the second wires respectively under condition that the insulating covers of the first and second wires have been fused.

The seventh feature of the invention resides in that the first direction is identical to a horizontal direction defined on the wiring board and the second direction is identical to a vertical direction substantially perpendicular to the horizontal direction.

As the eighth feature of the invention, there is further provided a method of forming a designated circuit for electrical connection box by using a wiring machine having a wiring head, the method comprising the steps of:

preparing a first wires and a wiring board having an insulating board and further allowing the wiring machine to retain the first wires;

operating the wiring machine to wire the first wires on the wiring board straight in a first direction defined on the wiring board, at predetermined intervals through the wiring head;

preparing a second wires and further allowing the wiring machine to retain the second wires;

operating the wiring machine to wire the second wires on the wiring board straight in a second direction defined on the wiring board, at predetermined intervals through the wiring head so that the second wires cross the first wires at respective intersections; and

preparing a plurality of pressure-welding terminals for electrically connecting the first wires with the second wires and further fitting the pressure-welding terminals on some of the intersections under pressure thereby to establish the designated circuit on the wiring board.

According to the above method of forming a circuit structure for electrical connection, the bending points of the wires can be eliminated since the first and second wires are wired straight at predetermined intervals and juxtaposed in the first and second directions.

Thus, since it becomes unnecessary to turn the wiring head in the course of wiring the wires by the wiring machine, it is possible to shorten a period required for the wiring operation. Correspondingly, it becomes possible to reduce the number of wiring machines, also reducing the installation cost.

Additionally, owing to the above-mentioned arrangement of the first and second wires, each overlap of the wires consists of two wires at most, so that the wiring board can be lowered in height thereby to save a space occupied by the wiring board in height.

As the ninth feature of the invention, there is also provided a method of forming a designated circuit for electrical connection box by using a wiring machine having a plurality of wiring heads juxtaposed therein, the method comprising the steps of:

preparing a first wires and a wiring board having an insulating board and further allowing the wiring machine to retain the first wires;

operating the wiring machine to simultaneously wire the first wires on the wiring board straight in a first direction defined on the wiring board, at predetermined intervals through the wiring heads juxtaposed;

preparing a second wires and further allowing the wiring machine to retain the second wires;

operating the wiring machine to simultaneously wire the second wires on the wiring board straight in a second direction defined on the wiring board, at predetermined intervals through the wiring heads juxtaposed so that the second wires cross the first wires at respective intersections; and

preparing a plurality of pressure-welding terminals for electrically connecting the first wires with the second wires and further fitting the pressure-welding terminals on some of the intersections under pressure thereby to establish the designated circuit on the wiring board.

According to this circuit forming method, in addition to effects similar to the method of the eighth feature, it is possible to shorten a period of the wiring operation remarkably since the first and second wires are respectively wired by the juxtaposed wiring heads simultaneously. Thus, it is possible to improve the workability in wiring furthermore.

As the tenth feature of the invention, there is further provided a method of forming a designated circuit for electrical connection box by using a wiring machine, the method comprising the steps of:

preparing a first wires and a wiring board having an insulating board and further allowing the wiring machine to retain the first wires;

operating the wiring machine to wire the first wires on the wiring board straight in a first direction defined on the wiring board, at predetermined intervals;

preparing a second wires and further allowing the wiring machine to retain the second wires;

operating the wiring machine to wire the second wires on the wiring board straight in a second direction defined on the wiring board, at predetermined intervals so that the second wires cross the first wires at respective intersections; and

connecting the first wires to the second wires at some of the intersections thereby to establish the designated circuit on the wiring board.

According to this method, since the designated circuit is formed without using the pressure-welding terminals, it is possible to improve the workability in connecting the first wires to the second wires.

As the eleventh feature of the invention, in the above method, the first wires and the second wires are together covered with insulating covers respectively.

As the twelfth feature of the invention, in the above method, the connecting step includes a step of fusing the insulating covers of the first and second wires by means of an ultrasonic welding machine.

These and other objects and features of the present invention will become more fully apparent from the following description and appended claims taken in conjunction with the accompany drawings.

### BRIEF DESCRIPTION OF THE DRAWINGS

FIG. 1 is a plan view showing the circuit structure of the electrical connection box as an example of the prior art;

FIG. 2 is a side view of FIG. 1;

FIG. 3 is a plan view showing the circuit structure of the electrical connection box in accordance with the first embodiment of the present invention;

FIG. 4 is a longitudinal sectional view of FIG. 3;

FIG. 5 is a perspective view showing a condition that necessary one of intersections defined by the wires in the horizontal direction and the wires in the vertical direction, is conducted electrically through a pressure-welding terminal; and

FIG. 6 is a perspective view showing a condition that the wires forming one intersection defined by one wire in the horizontal direction and another wire in the vertical direction, are welded with each other.

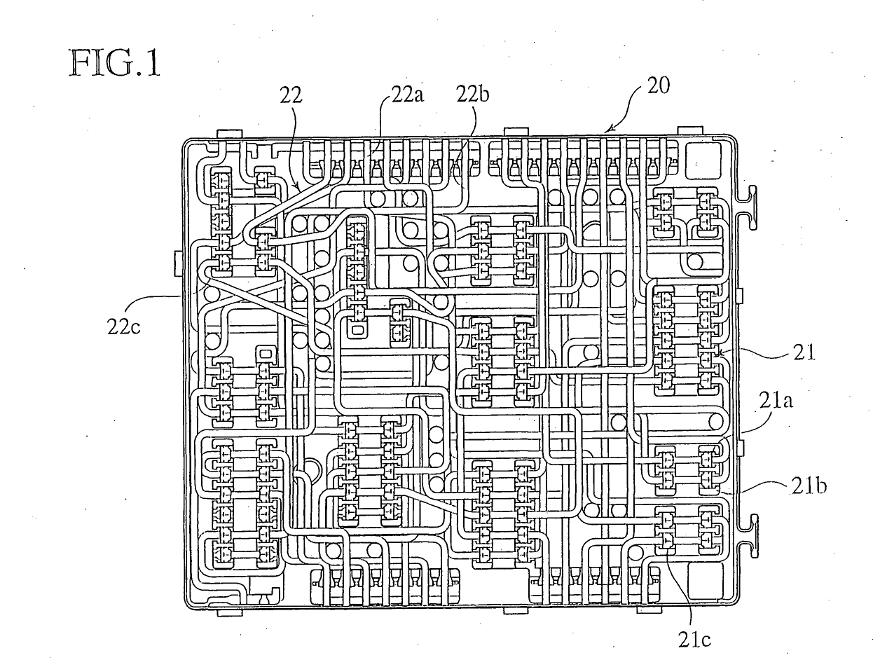

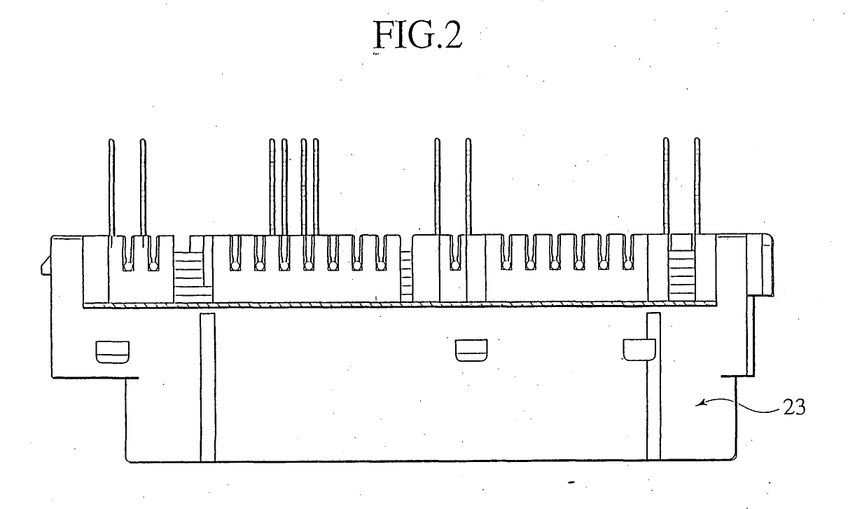

### BEST MODE OF EMBODIMENTS OF THE INVENTION

Embodiments of the circuit structure and circuit-forming method for electrical connection box of the present invention will be described later.

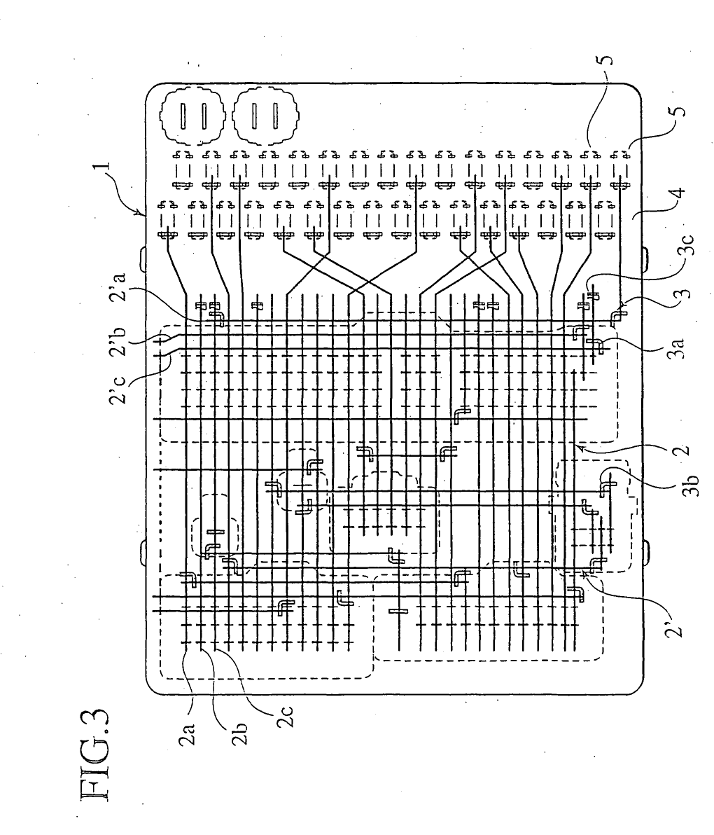

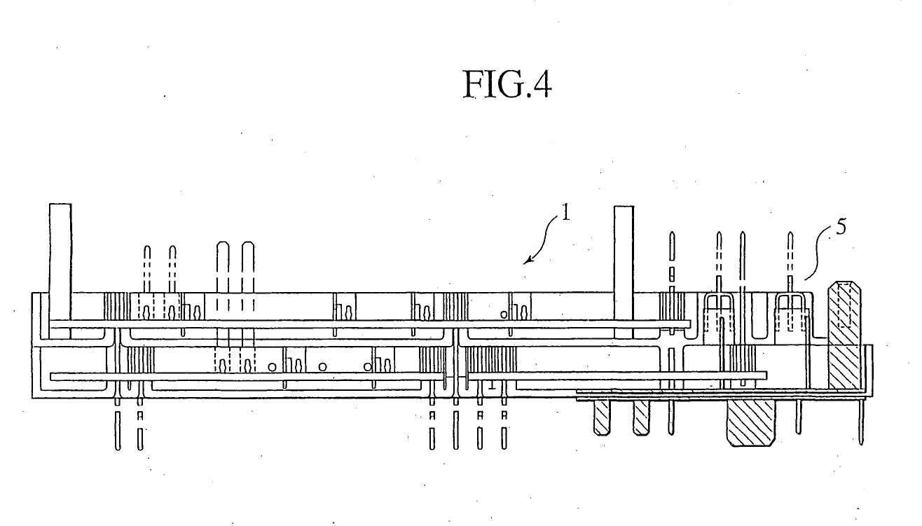

As shown in FIGS. 3 and 4, the circuit structure for electrical connection box includes a wiring board 1, a plurality of first wires 2, a plurality of second wires 2′ and a plurality of pressure-welding terminals 3. The wiring board 1 is made from an insulating substrate 4. In the assembled state shown in the figure, The pressure-welding terminal 3 (3a, 3b, 3c, . . . ) are fitted and supported on the insulating substrate 4. In the embodiment, the first wires 2 (2a, 2b, 2c, . . . ) are wired straight in a first direction (i.e. horizontal direction in the figure) on the wiring board 1. The wires 2 (2a, 2b, 2c, . . . ) are parallel with each other at predetermined intervals. While, the second wires 2′ (2′a, 2′b, 2′c, . . . ) are wired straight in a second (vertical) direction on the wiring board 1. Similarly, the wires 2′ (2′a, 2′b, 2′c, . . . ) are parallel with each other at predetermined intervals. In detail, the above horizontal direction of the embodiment is defined to cross the vertical direction at right angles. Consequently, there are established a number of intersections between the first and second wires 2 on the wiring board 1.

In order to form a designated circuit on the wiring board 1, some of the intersections are selected and thereafter, the first and second wires forming each intersection on selection are electrically connected with each other by welding the pressure-welding terminal 3 (3a, 3b, 3c, . . . ) to them under pressure.

Note, reference numeral 5 in the figure designates an electrical fuse.

Next, the method of forming the above circuit will be described.

First, by means of a not-shown wiring machine with a wiring head, it is performed to wire the first wires 2 (2a, 2b, 2c, . . . ) one by one straight so as to extend parallel with each other in the horizontal direction on the wiring board 1 at the predetermined intervals.

Next, using the same wiring head, it is further performed to wire the second wires 2′ (2′a, 2′b, 2′c, . . . ) one by one straight so as to extend parallel with each other in the vertical direction crossing the above wiring direction at right angles, at the predetermined intervals.

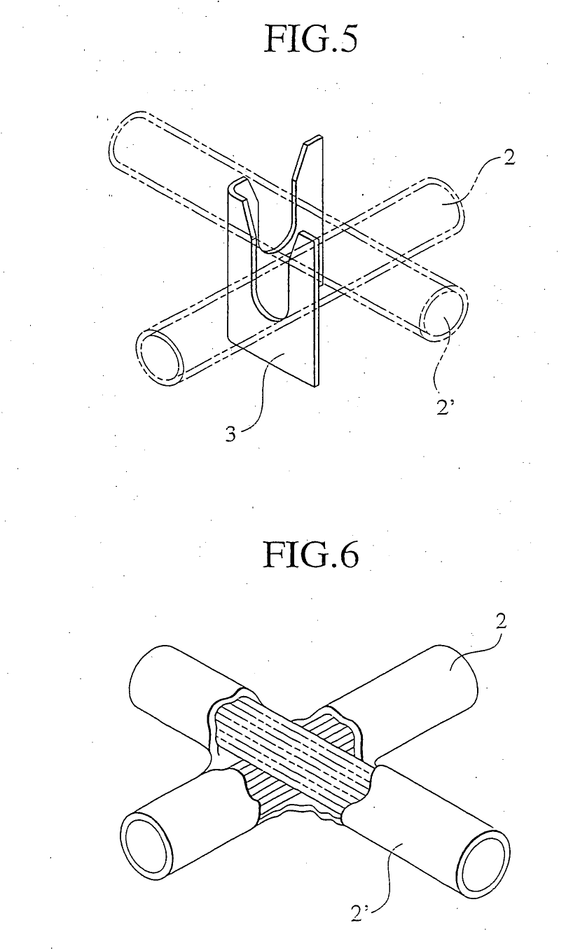

Then, as mentioned above, the essential intersections formed by the first wires 2 (2a, 2b, 2c, . . . ) of the horizontal direction and the second wires 2′ (2′a, 2′b, 2′c, . . . ) of the vertical direction are welded under pressure by the pressure-welding terminal 3 (3a, 3b, 3c, . . . ) for respective conductivity, as shown in FIG. 5. In this way, the desired circuit can be established on the wiring board.

Repeatedly, the essential intersections are welded under pressure by the pressure-welding terminal 3 (3a, 3b, 3c, . . . ) in the above-mentioned embodiment. In the modification, as representatively shown in FIG. 6, the first wire 2 may be connected to the second wire 2′ directly without using any pressure-welding terminal. As means for accomplishing such a direct connection between the first and second wires 2 and 2′, for example, there exists an ultrasonic welding machine which can fuse insulating covers of the wires 2 and 2′ to connect their conductive parts (core lines) with each other. As a matter of course, it is noted that the wires 2 and 2′ have to be laid to overlap each other in advance of ultrasonic welding of the wires by the ultrasonic welding machine.

In common with the embodiment and the modification, it is possible to eliminate the bending points that have been commonly associated with the conventional circuit structure since the first wires 2 (2a, 2b, 2c, . . . ) and the second wires 2′ (2′a, 2′b, 2′c, . . . ) are wired straight in two directions: horizontal direction on the wiring board 1 and vertical direction crossing the horizontal direction at right angles. In other words, it becomes unnecessary to turn the wiring head in the course of wiring the wires by the wiring machine. Therefore, it is possible to shorten a period required for the wiring operation.

Correspondingly, it becomes possible to reduce the number of wiring machines, also reducing the installation cost.

Repeatedly, the first wires 2 are wired straight in the horizontal direction on the wiring board 1 and the second wires 2′ are wired straight in the vertical direction crossing the wiring direction of the first wires 2 at right angles. Thus, each overlap of the wires 2, 2′ consists of two wires at most, so that the wiring board 1 can be lowered in height to save the space occupied by the board 1 in height.

The above embodiment (including the modification of FIG. 6) is an example illustrative of wiring the wires one by one at predetermined intervals by using the single wiring head. Now, we describe an example of using a not-shown wiring machine having a plurality of wiring heads juxtaposed therein.

Upon juxtaposing the plural wiring heads in the not-shown wiring machine, it is established that the interval of the adjoining wiring heads becomes equal to an interval of the adjoining wires. Thereupon, by using the plural wiring heads, the first wires 2 (2a, 2b, 2c, . . . ) are wired and juxtaposed in the horizontal direction on the wiring board 1 straight and simultaneously. Similarly, the second wires 2′ (2′a, 2′b, 2c, . . . ) are wired and juxtaposed in the vertical direction on the wiring board 1 straight and simultaneously. Then, some intersections essential to the designated circuit are electrically connected with each other by the pressure-welding terminals 3 (3a, 3b, 3c . . . ) or ultrasonic welding.

In addition to effects similar to those in the circuit-forming method of the above embodiment, the first and second wires 2 and 2′ are wired by the juxtaposed wiring heads simultaneously. Therefore, it is possible to shorten the period of wiring operation remarkably, thereby improving the workability of wiring furthermore.

Although the above embodiment is an example illustrative of wiring the covered wires, the above method-is also applicable to form the circuit in-case of wiring flat cables on the wiring board.

Further, the above embodiment is an example illustrative of wiring the horizontal and vertical wires crossing at right angles. Nevertheless, the wires in the horizontal and vertical directions do not always cross at right angles so long as they cross each other. Again, although the above embodiment is an example illustrative of wiring the wires on the flat wiring board, they may be wired on a curved wiring board allowing of the straight wiring.

Additionally, the wires in the horizontal direction may be laid on the wires in the vertical direction, and vice versa.

Finally, it will be understood by those skilled in the art that the foregoing description are preferred embodiments of the disclosed circuit structure and method of forming the circuit. Various changes and modifications may be made to the present invention without departing from the scope of the invention.

1-7. (canceled)

8. A method of forming a designated circuit for an electrical connection box by using a wiring machine having a wiring head, the method comprising the steps of:
preparing a wiring board having an insulating board;
retaining a plurality of first wires in the wiring machine;
operating the wiring machine to wire the plurality of first wires on the wiring board straight in a first direction defined on the wiring board at predetermined intervals using the wiring head;
retaining a plurality of second wires in the wiring machine;
operating the wiring machine to wire the plurality of second wires on the wiring board straight in a second direction defined on the wiring board at predetermined intervals using the wiring head, wherein the plurality of second wires cross the Plurality of first wires at respective intersections;
preparing a plurality of pressure-welding terminals for electrically connecting the Plurality of first wires with the plurality of second wires; and
fitting the plurality of pressure-welding terminals on some of the intersections under pressure to establish the designated circuit on the wiring board.

9. A method of forming a designated circuit for an electrical connection box by using a wiring machine having a plurality of wiring heads juxtaposed therein, the method comprising the steps of:
preparing a wiring board having an insulating board;
retaining a plurality of first wires in the wiring machine;
operating the wiring machine to simultaneously wire the plurality of first wires on the wiring board straight in a first direction defined on the wiring board at predetermined intervals using the plurality of wiring heads juxtaposed therein;
retaining a plurality of second wires in the wiring machine;
operating the wiring machine to simultaneously wire the plurality of second wires on the wiring board straight in a second direction defined on the wiring board at predetermined intervals using the plurality of wiring heads juxtaposed therein, wherein the plurality of second wires cross the plurality of first wires at respective intersections;
preparing a plurality of pressure-welding terminals for electrically connecting the Plurality of first wires with the Plurality of second wires; and
fitting the pressure-welding terminals on some of the intersections under pressure to establish the designated circuit on the wiring board.

10. A method of forming a designated circuit for an electrical connection box by using a wiring machine, the method comprising the steps of:
preparing a wiring board having an insulating board;
retaining a plurality of first wires in the wiring machine;
operating the wiring machine to wire the plurality of first wires on the wiring board straight in a first direction defined on the wiring board at predetermined intervals;
retaining a plurality of second wires in the wiring machine;
operating the wiring machine to wire the plurality of second wires on the wiring board straight in a second direction defined on the wiring board at predetermined intervals, wherein the plurality of second wires cross the plurality of first wires at respective intersections; and
connecting the plurality of first wires to the plurality of second wires at the some intersections to establish the designated circuit on the wiring board.

11. The method of forming the designated circuit for the electrical connection box as claimed in claim 10, wherein the plurality of first wires and the plurality of second wires are together covered with insulating covers respectively.

12. The method of forming the designated circuit for the electrical connection box as claimed in claim 11, wherein the connecting step further comprises:
a step of fusing the insulating covers of the plurality of first and second wires by means of an ultrasonic welding machine.
